(19) United States
(12) Patent Application Publication
(10) Pub. No.: US 2016/0285460 A1
(43) Pub. Date: Sep. 29, 2016

(54) OVEN CONTROLLED CRYSTAL OSCILLATOR USING EMBEDDED HEATING DEVICE PACKAGE

(71) Applicant: TXC CORPORATION, TAIPEI (TW)

(72) Inventors: CHIEN-WEI CHIANG, TAO YUAN COUNTY (TW); CHE-LUNG HSU, TAO YUAN COUNTY (TW); CHEN-YA WENG, TAO YUAN COUNTY (TW); CHIA-WEI CHEN, TAO YUAN COUNTY (TW)

(21) Appl. No.: 15/066,274

(22) Filed: Mar. 10, 2016

(30) Foreign Application Priority Data
Mar. 27, 2015 (TW) 104110076

(51) Int. Cl. H03L 1/02; H03L 1/04

(52) U.S. Cl. CPC H03L 1/028; H03L 1/04

(57) ABSTRACT

An oven controlled crystal oscillator using an embedded heating device package is disclosed. The oven controlled crystal oscillator, which is different from the conventional technology using a heating source independent from a quartz crystal package, integrates a heating resistor in a ceramic package structure of the quartz crystal and cooperates with a temperature-controlled circuit to heat a quartz blank in the quartz crystal package, thereby shortening thermal conduction paths, increasing thermal conduction efficiency and greatly reducing thermal dissipation. The present invention further uses an exterior and independent heating resistor, combining with the heating resistor in the quartz crystal package and controlled by the temperature-controlled circuit to form a sandwich structure so that heat is more concentrated to use, thereby stabilizing the interior temperature of a constant temperature oven and the output frequency of an oscillator.

This application claims priority for Taiwan patent application no. 104110076 filed on Mar. 27, 2015, the content of which is incorporated in its entirely.

### BACKGROUND OF THE INVENTION

1. Field of the Invention

The present invention relates to an oven controlled crystal oscillator, particularly to an oven controlled crystal oscillator using a heating device embedded in a quartz crystal package.

2. Description of the Related Art

An oven controlled crystal oscillator (OCXO) mainly uses its temperature-controlled circuit and hermetical structure to fix a specific working temperature of a quartz crystal. As a result, the output frequency variation induced by the ambient temperature variation is reduced to the minimum, so as to stabilize the output frequency of the oscillator.

Refer to FIG. 1A. In the conventional technology, an exterior housing 11 and a bottom circuit board 12 of an OCXO 10 form an interior chamber space as a constant temperature oven. An oscillation circuit 16 and a quartz crystal 15 are arranged at one side of an interior circuit board 13 in the exterior housing 11. Usually, the oscillation circuit 16 and the quartz crystal 15 are arranged above the interior circuit board 13. As shown in FIG. 1B, a quartz blank 151 of the quartz crystal 15 is encapsulated in an airtight chamber space formed by a ceramic package 153. A heater 14 and a temperature-controlled circuit 17 are arranged at another side of the interior circuit board 13. The heater 14, like a heating source, heats the quartz blank 151 in the quartz crystal 15 to a specific working temperature, thereby stabilizing the temperature of the quartz blank 151 in the constant temperature oven. However, the interior circuit board 13 separates the heating source (the heater 14) from the quartz crystal 15. Also, the heating source heats the quartz blank 151 through the ceramic package 153 of the quartz crystal 15. In other words, thermal conduction paths between the heating source and the quartz blank 151 are long. The thermal conduction efficiency of the heating source heating the quartz blank 151 is worse. Thus, it is hard to maintain the stability of the constant temperature oven.

Compared with the conventional OCXO with a larger volume, the temperature stability of a constant temperature oven of a miniaturized OCXO is not easy to be maintained due to the restriction of a small volume that is limited by its small interior chamber size, and the miniaturized OCXO is easily affected by the exterior temperature variation. Therefore, the applicant of the present invention provides an oven controlled crystal oscillator using a heating device embedded in a quartz crystal package, which embeds a heating resistor in the quartz crystal package so that the heating source directly heats a quartz blank to reduce thermal conduction paths between the heating source and the quartz blank and decrease the thermal dissipation of the heater, and which improves the factors affecting the temperature stability to stabilize the oscillation frequency outputted, thereby overcoming the above-mentioned problems.

### SUMMARY OF THE INVENTION

In order to overcome the drawbacks of the existing technology, a primary objective of the present invention is to provide an oven controlled crystal oscillator using a heating device embedded in a quartz crystal package, which integrates an exterior and independent heating resistor of the conventional technology into a ceramic package structure of a quartz crystal, so as to directly heat a quartz blank, thereby shortening thermal conduction paths, increasing thermal conduction efficiency and reducing thermal dissipation of the heating device.

Another objective of the present invention is to provide a miniaturized oven controlled crystal oscillator, which uses a heating resistor that is embedded in a quartz crystal, combining with an exterior and independent heating resistor that are controlled by the temperature-controlled circuit to form a sandwich structure to heat the quartz blank from both side, so as to concentrate the heat generated by the two heater elements on the quartz crystal for use, whereby the temperature variation of the sandwich structure is not easily affected by the air flow exterior to the housing to easily stabilize the output frequency of an oscillator.

To achieve the above-mentioned objectives, the present invention provides an oven controlled crystal oscillator using a heating device embedded in a quartz crystal package. The oven controlled crystal oscillator comprises an exterior housing, an exterior circuit board, an interior circuit board, a heating resistor, a quartz crystal, an oscillation circuit and a temperature-controlled circuit. The exterior housing and the exterior circuit board can form a hermetic interior chamber space provided to other elements for assembly. A top of the exterior circuit board has a first assembly surface. The interior circuit board is arranged in the interior chamber space. A top and a bottom of the interior circuit board respectively have a second assembly surface and a third assembly surface. The interior circuit board is electrically connected with the first assembly surface of the exterior circuit board through a plurality of metal leads. The quartz crystal is arranged on the second assembly surface of the interior circuit board. A main body of the quartz crystal is a ceramic package with a heating resistor embedded therein. A top of the ceramic package is sealed by an upper metal lid cover to form an airtight chamber space in an interior of the quartz crystal. The quartz blank is mounted on the ceramic package through at least one piece of electricity conduction glue and arranged in the airtight chamber space. The temperature-controlled circuit and the oscillation circuit are arranged on the first assembly surface of the exterior circuit board or the third assembly surface of the interior circuit board.

The present invention provides another oven controlled crystal oscillator using a heating device embedded in a quartz crystal package, which comprises an exterior housing, an exterior circuit board, an interior circuit board, a first heating resistor, a quartz crystal, an oscillation circuit and a temperature-controlled circuit. The exterior housing and the exterior circuit board can form a hermetic interior chamber space provided to other elements for assembly. A top of the exterior circuit board has a first assembly surface. The interior circuit board is arranged in the interior chamber space. A top and a bottom of the interior circuit board respectively have a second assembly surface and a third assembly surface. The interior circuit board is electrically connected with the first assembly surface of the exterior circuit board through a plurality of metal leads. The first heating resistor is arranged on the third assembly surface of the interior circuit board, and a bottom of the first heating resistor has a fourth assembly surface. The quartz crystal is arranged on the fourth assembly surface of the first heating resistor. A main body of the quartz crystal is a ceramic package with a second heating resistor embedded therein. A top of the ceramic package is sealed by an upper metal lid cover to form an airtight chamber space in an interior of the quartz crystal. The quartz blank is mounted on the ceramic package through at least one piece of electricity conduction glue and arranged in the airtight chamber space. The temperature-controlled circuit is arranged on the third assembly surface or the second assembly surface of the interior circuit board or the first assembly surface of the exterior circuit board. The oscillation circuit is arranged on the first assembly surface of the exterior circuit board.

In other words, in the oven controlled crystal oscillator using the heating device embedded in the quartz crystal package of the present invention, the heating resistor is arranged in the ceramic package structure of the quartz crystal and directly heats the quartz blank inside the quartz crystal package to effectively shorten thermal conduction paths and reduce power consumption. Besides, the present invention uses an exterior and independent heating resistor, combining with the heating resistor in the quartz crystal package that are controlled by the temperature-controlled circuit to form a sandwich structure so that heat is more concentrated to use, thereby stabilizing the interior temperature of a constant temperature oven and the output frequency of an oscillator.

Below, the embodiments are described in detail in cooperation with the drawings to make easily understood the technical contents, characteristics and accomplishments of the present invention.

### BRIEF DESCRIPTION OF THE DRAWINGS

FIG. 1A and FIG. 1B are respectively a diagram schematically showing an oven controlled crystal oscillator and its quartz crystal package in the conventional technology;

FIG. 2 is a diagram schematically showing an oven controlled crystal oscillator using a heating device embedded in a quartz crystal package according to an embodiment of the present invention;

FIG. 3 is a diagram schematically showing another oven controlled crystal oscillator using a heating device embedded in a quartz crystal package according to an embodiment of the present invention;

FIG. 4 is a diagram schematically showing a further oven controlled crystal oscillator using a heating device embedded in a quartz crystal package according to an embodiment of the present invention;

FIG. 5 is a diagram schematically showing an oven controlled crystal oscillator using a heating device embedded in a quartz crystal package and an exterior and independent heating resistor according to an embodiment of the present invention; and

FIG. 6 is a diagram schematically showing another oven controlled crystal oscillator using a heating device embedded in a quartz crystal package and an exterior and independent heating resistor according to an embodiment of the present invention.

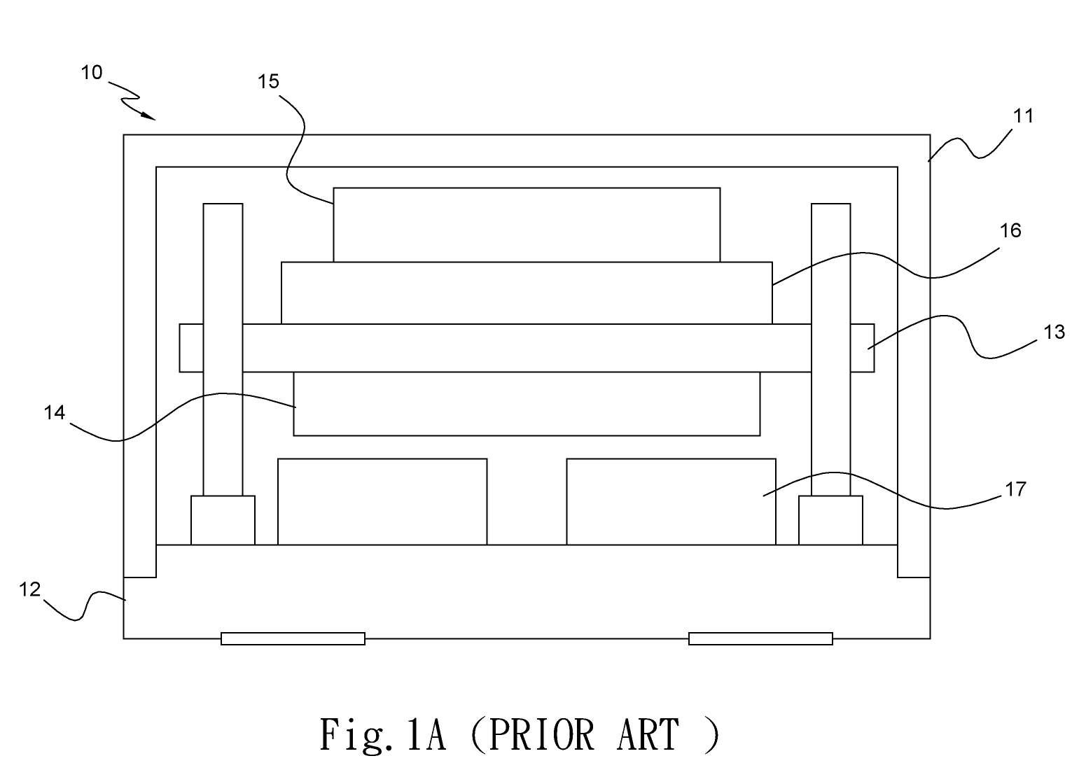

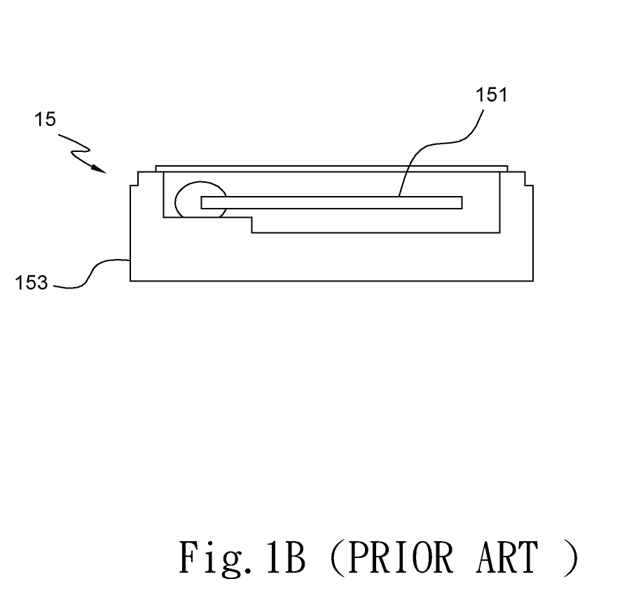

### DETAILED DESCRIPTION OF THE INVENTION

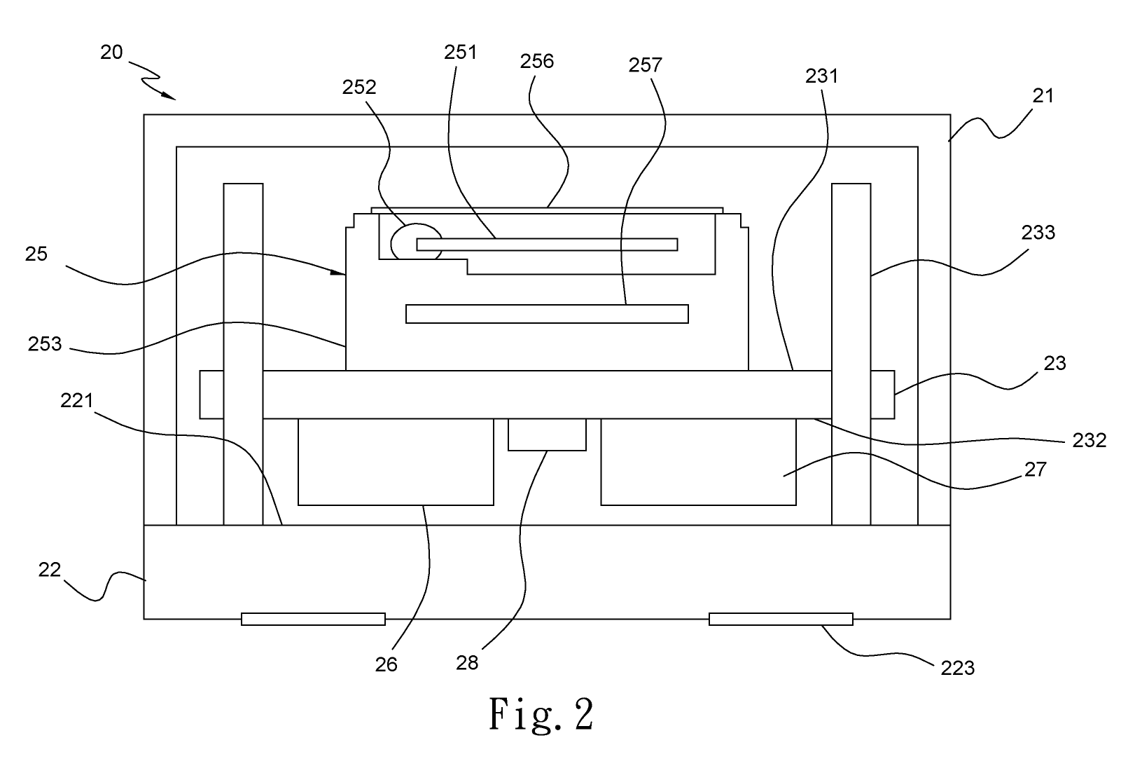

The present invention disclosed an oven controlled crystal oscillator using a heating device embedded in a quartz crystal package. Refer to FIG. 2, which is a cross section showing an oven controlled crystal oscillator 20 using a heating device embedded in a quartz crystal package according to the first embodiment of the present invention.

In the embodiment, the oven controlled crystal oscillator 20 using the heating device embedded in the quartz crystal package mainly comprises an exterior housing 21, an exterior circuit board 22, an interior circuit board 23, a quartz crystal 25, an oscillation circuit 26 and a temperature-controlled circuit 27. Below is the detail introduction of each element.

The exterior housing 21 of the embodiment is made of metal or plastic. Compared with a ceramic housing, the exterior housing 21 has a smaller volume and makes heat hard to be dissipated. The exterior housing 21 can be made of metal whose thermal conductivity is relatively low, such as stainless steel. Since the thermal conduction coefficients of stainless steel, brass, and nickel silver are respectively 16.3 W/mK, 115 W/mK and 23˜29 W/mK, the exterior housing 21 is perfectly made of stainless steel with lower thermal conductivity. The exterior circuit board 22 is arranged on a bottom of the exterior housing 21 whereby the exterior circuit board 22 and the exterior housing 21 define a hermetic interior chamber space of a constant temperature oven provided to other elements for assembly (as described below). A top of the exterior circuit board 22 has a first assembly surface 221, and other elements are arranged above the first assembly surface 221. Besides, a bottom of the exterior circuit board 22 has a plurality of exterior electrodes 223 electrical connected with exterior elements.

A top and a bottom of the interior circuit board 23 respectively have a second assembly surface 231 and a third assembly surface 232, and the interior circuit board 23 is electrically connected with the first assembly surface 221 of the exterior circuit board 22 via a plurality of metal leads 233. The metal leads 233 can be made of metal whose thermal conductivity is relatively low, such as KOVAR Fe—Co—Ni alloy. Since the thermal conduction coefficients of KOVAR Fe—Co—Ni alloy, brass, and nickel silver are respectively 17.3 W/mK, 115 W/mK and 23˜29 W/mK, the metal leads 233 are perfectly made of KOVAR Fe—Co—Ni alloy with lower thermal conductivity. The second assembly surface 231 of the interior circuit board 23 is provided with the quartz crystal 25. The third assembly surface 232 of the interior circuit board 23 is provided with the oscillation circuit 26 and the temperature-controlled circuit 27 composed of a discrete circuit, wherein the temperature-controlled circuit 27 comprises a temperature-controlled circuit control element and a temperature-controlled circuit adjustment element, and wherein the oscillation circuit 26 is formed by an oscillation circuit chip connected with a ceramic package via conduction wires. Besides, the third assembly surface 232 of the interior circuit board 23 is provided with a thermistor 28. In practice, the thermistor 28 is also arranged on the second assembly surface 231 of the interior circuit board 23.

As shown in the figure, the quartz crystal 25 is formed using a quartz blank 251 mounted in a ceramic package 253 through electricity conduction glue 252. A top of the ceramic package 253 is sealed by an upper metal lid cover 256 to form an airtight chamber space in an interior of the quartz crystal 25. Especially, the present invention embeds a heating resistor 257 in an inner structure of the ceramic package 253, so that the heating resistor 257 cooperates with the temperature-controlled circuit 27 to directly heat the quartz blank 251 in the quartz crystal 25, thereby shortening thermal conduction paths, increasing thermal conduction efficiency, concentrating heat on the ceramic package 253 of the quartz crystal 25 and effectively avoiding thermal dissipation.

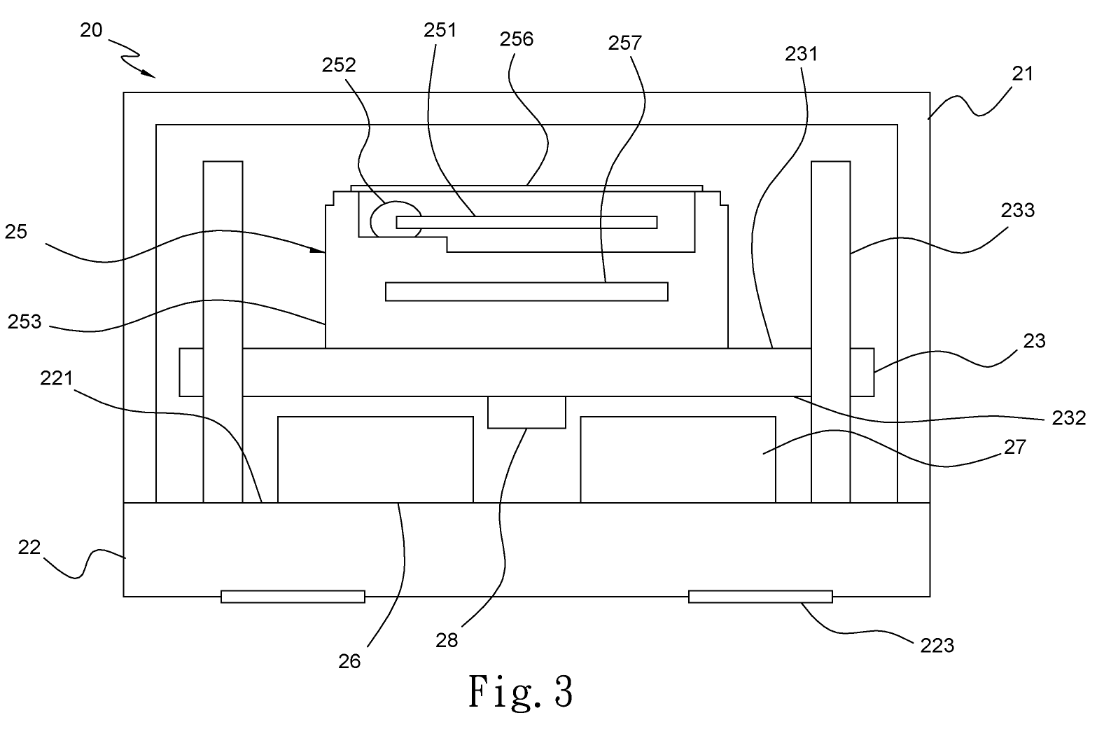

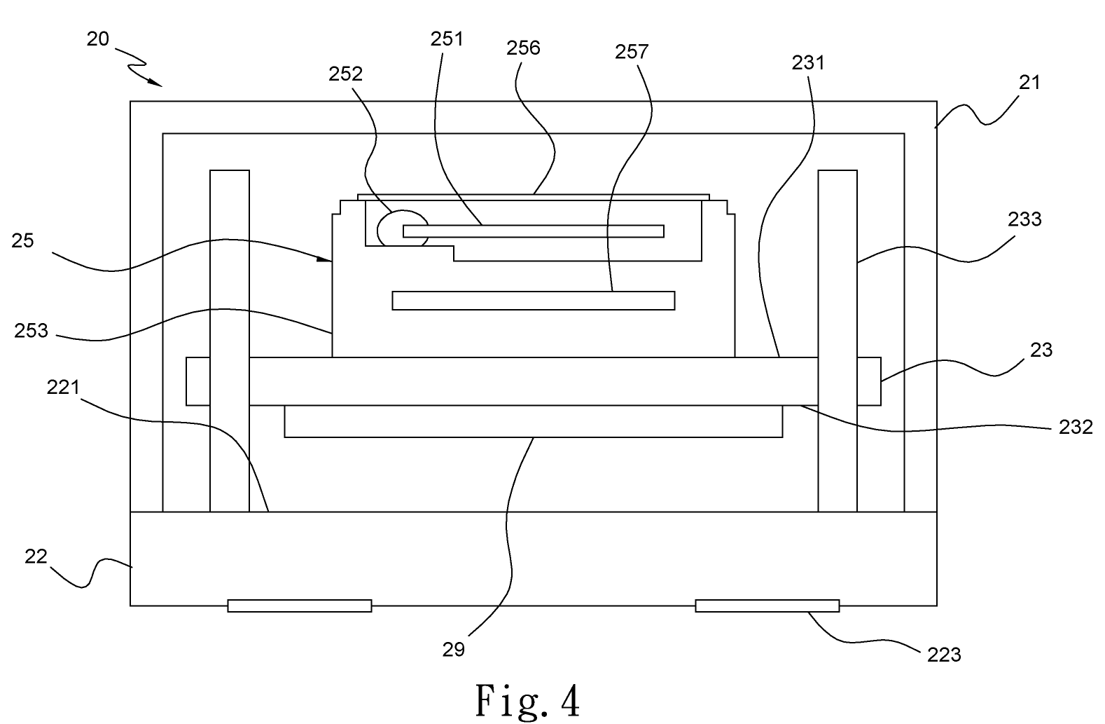

In addition, refer to FIG. 3. The temperature-controlled circuit 27 and the oscillation circuit 26 of the above-mentioned embodiment are also arranged on the first installation surface 221 of the exterior circuit board 22. Moreover, refer to FIG. 4, the temperature-controlled circuit 27 and the oscillation circuit 26 can form an integrated circuit 29 to decrease the amount of the essential elements.

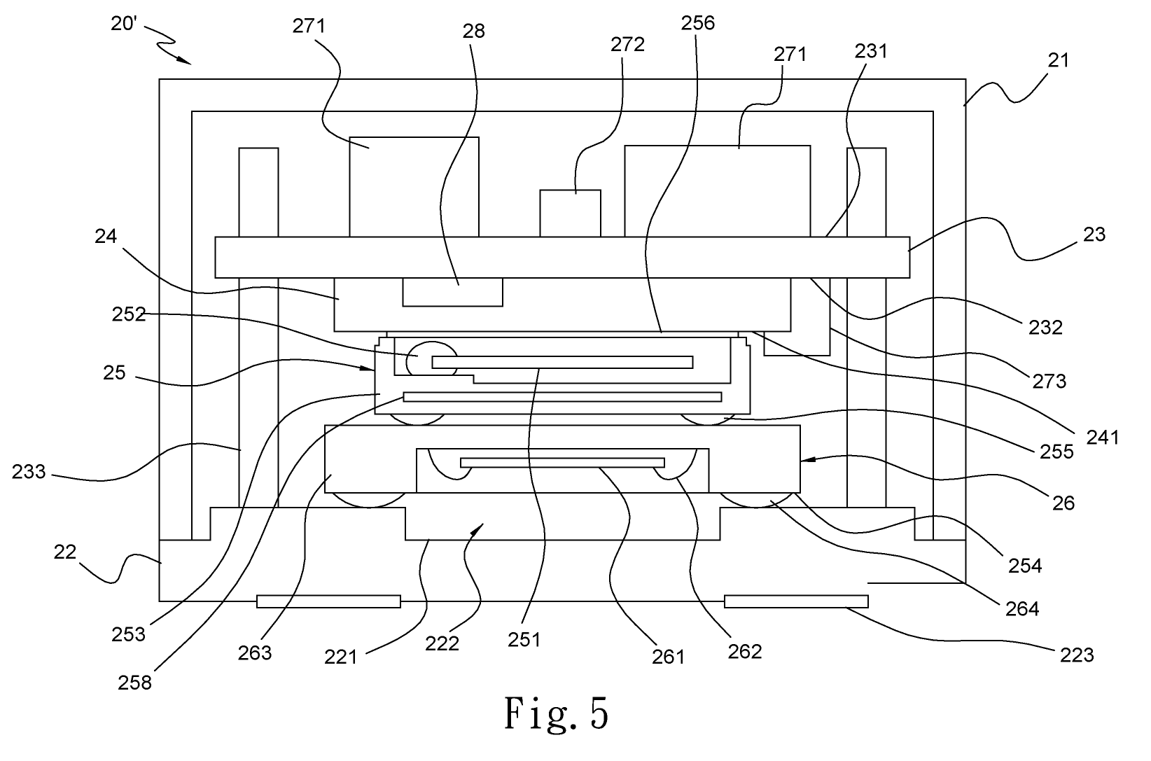

Furthermore, the above-mentioned embodiment can use an independent and exterior heating resistor, combining with the heating resistor in the quartz crystal that are controlled by the temperature-controlled circuit to form a sandwich structure whereby heat is more concentrated to use. Refer to FIG. 5, which is a cross section showing a miniaturized oven controlled crystal oscillator 20′ with low power consumption.

In the embodiment, the miniaturized oven controlled crystal oscillator 20′ with low power consumption mainly comprises an exterior housing 21, an exterior circuit board 22, an interior circuit board 23, a first heating resistor 24, a quartz crystal 25, an oscillation circuit 26 and a temperature-controlled circuit 27 (comprising temperature-controlled circuit control elements 271 and 273 and a temperature-controlled circuit adjustment element 272). Below is the detail introduction of each element.

The exterior housing 21 of the embodiment is made of metal or plastic. Compared with a ceramic housing, the exterior housing 21 has a smaller volume and makes heat hard to be dissipated. The exterior housing 21 can be made of metal whose thermal conductivity is relatively low, such as stainless steel. Since the thermal conduction coefficients of stainless steel, brass and nickel silver are respectively 16.3 W/mK, 115 W/mK and 23˜29 W/mK, the exterior housing 21 is perfectly made of stainless steel with lower thermal conductivity. The exterior circuit board 22 is arranged on a bottom of the exterior housing 21 whereby the exterior circuit board 22 and the exterior housing 21 define a hermetic interior chamber space of a constant temperature oven provided to other elements for assembly (as described below). A top of the exterior circuit board 22 has a first assembly surface 221, and other elements are arranged above the first assembly surface 221. In the embodiment, the first assembly surface 221 of the exterior circuit board 22 is provided with a heat-cut groove 222, which reduces the contact area between the inner structure and the exterior circuit board 22, and which reduce the phenomenon that heat dissipates from the exterior circuit board 22 to the outside, and which helps stabilize the temperature of the constant temperature oven. More specifically, compared with a circuit board being a flat plate structure, the first assembly surface 221 of the exterior circuit board 22 of the present invention is provided with solder 264 as essential soldering points, and the other part of the first assembly surface 221 dents downward to form a semi-hollow structure whereby a middle part surrounded by the soldering region forms the heat-cut groove 222 shown in the figure, thereby decreasing the contact area between the exterior circuit board 22 and other elements and not easily dissipating heat from the surface of the exterior circuit board 22 to the outside. Besides, a bottom of the exterior circuit board 22 has a plurality of exterior electrodes 223 electrical connected with exterior elements.

A top and a bottom of the interior circuit board 23 respectively have a second assembly surface 231 and a third assembly surface 232, and the interior circuit board 23 is electrically connected with the first assembly surface 221 of the exterior circuit board 22 via a plurality of metal leads 233. The metal leads 233 can be made of metal whose thermal conductivity is relatively low, such as KOVAR Fe—Co—Ni alloy. Since the thermal conduction coefficients of KOVAR Fe—Co—Ni alloy, brass, and nickel silver are respectively 17.3 W/mK, 115 W/mK and 23˜29 W/mK, the metal leads 233 are perfectly made of KOVAR Fe—Co—Ni alloy with lower thermal conductivity. The second assembly surface 231 of the interior circuit board 23 is provided with the temperature-controlled circuit control element 271 and the temperature-controlled circuit adjustment element 272 which both composed of discrete circuits. Additionally, the third assembly surface 232 of the interior circuit board 23 is provided with the temperature-controlled circuit control element 273, the first heating resistor 24 and a thermistor 28.

A bottom of the first heating resistor 24 has a fourth assembly surface 241 which is provided with the quartz crystal 25.

The quartz crystal 25 is formed using a quartz blank 251 mounted in a ceramic package 253 through electricity conduction glue 252. A top of the ceramic package 253 is sealed by an upper metal lid cover 256 to form an airtight chamber space in an interior of the quartz crystal 25. As described in the above-mentioned embodiment, the present invention especially embeds a second heating resistor 258 in an inner structure of the ceramic package 253, so that the second heating resistor 258 cooperates with the temperature-controlled circuit to directly heat the quartz blank 251 in the quartz crystal 25, thereby shortening thermal conduction paths, increasing thermal conduction efficiency, concentrating heat on the ceramic package 253 of the quartz crystal 25 and effectively avoiding thermal dissipation. Meanwhile, the upper metal lid cover 256 on the top of the quartz crystal 25 directly touches the fourth assembly surface 241 on the bottom of the first heating resistor 24 whereby the first heating resistor 24 directly heats the surface of the quartz crystal 25. The quartz blank 251 is sandwiched in between the first heating resistor 24 and the second heating resistor 258 to form a heating structure whereby heat is not easily dissipated but concentrates. The sandwich structure of the present invention is difficulty affected by air flow and helps stabilize the temperature of the constant temperature oven.

In order to achieve the purpose that the bottom of the first heating resistor 24 tightly touches the upper metal lid cover 256 on the top of the quartz crystal 25, the upper metal lid cover 256 is fixed to the first heating resistor through a medium with good thermal conductivity, such as thermal conduction glue. A bottom of the quartz crystal 25 has a fifth assembly surface 254. The fifth assembly surface 254 of the quartz crystal 25 is provided with the oscillation circuit 26 through solder 255.

The oscillation circuit 26 is formed by an oscillation circuit chip 261 connected with a ceramic package 263 via conduction wires 262. As the above-mentioned, a top of the oscillation circuit 26 joins the fifth assembly surface 254 of the quartz crystal 25 through the solder 255, and a bottom of the oscillation circuit 26 joins the first assembly surface 221 of the exterior circuit board 22 through solder 264 whereby the oscillation circuit 26 is arranged between the exterior circuit board 22 and the quartz crystal 25. The heat-cut grove 222 separates the bottom of the oscillation circuit 26 from the first assembly surface 221. In a way of soldering the solder 264, the contact area between the oscillation circuit 26 and the first assembly surface 221 of the exterior circuit board 22 only includes soldering points (the solder 264) at corners of the oscillation circuit board 26, thereby decreasing the thermal conduction area and avoiding the thermal dissipation.

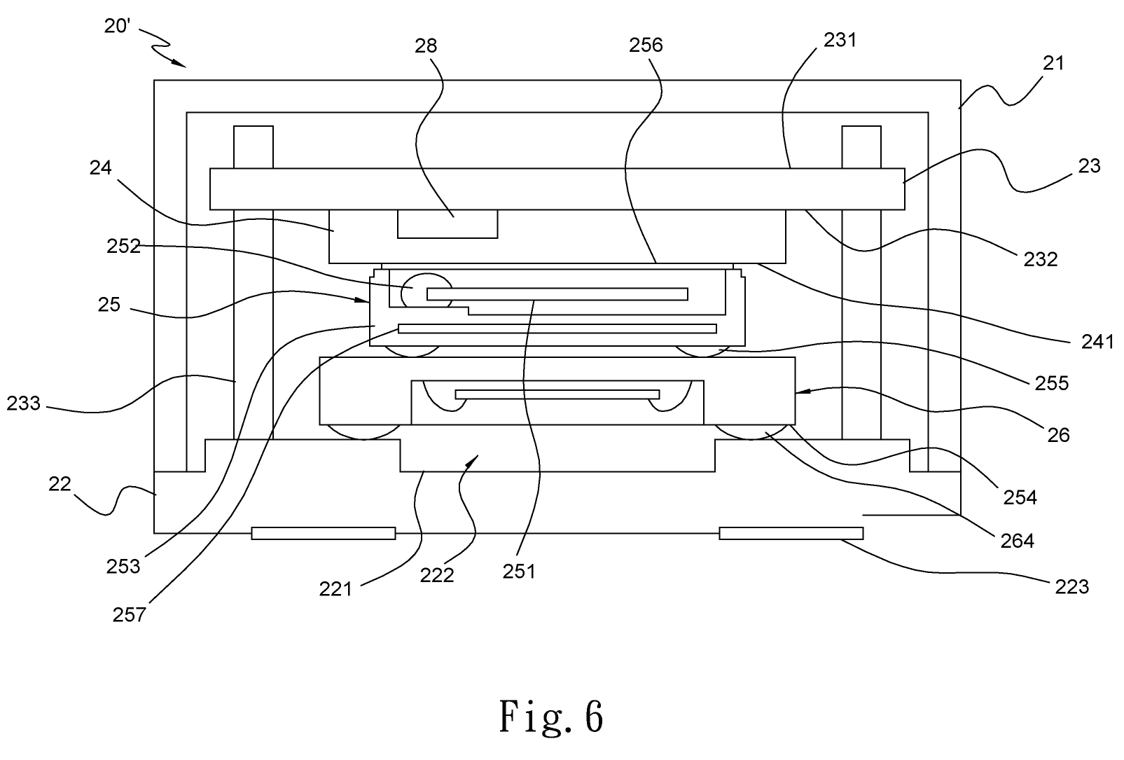

Moreover, refer to FIG. 6. In the embodiment, the temperature-controlled circuit 27 and the oscillation circuit 26 can form an integrated circuit 29 to decrease the amount of the essential elements.

In conclusion, the oven controlled crystal oscillator using the heating device embedded in the quartz crystal package of the present invention integrates the heating resistor in the ceramic package structure of the quartz crystal and cooperates with the temperature-controlled circuit to heat the quartz blank in the quartz crystal package, thereby shortening thermal conduction paths, increasing thermal conduction efficiency and greatly reducing thermal dissipation. The present invention further uses the exterior and independent heating resistor, the heating resistor in the quartz crystal package and the quartz blank controlled by heat so as to form a sandwich structure so that heat is more concentrated to use, thereby stabilizing the interior temperature of the constant temperature oven and the output frequency of the oscillator.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. An oven controlled crystal oscillator using a heating device embedded in a quartz crystal package comprising:
an exterior housing;
an exterior circuit board arranged on a bottom of said exterior housing and cooperating with said exterior housing to define a hermetic interior chamber space, and a top of said exterior circuit board has a first assembly surface;
an interior circuit board arranged in said interior chamber space and electrically connected with said first assembly surface of said exterior circuit board through a plurality of metal leads, and a top and a bottom of said interior circuit board respectively have a second assembly surface and a third assembly surface;
a quartz crystal arranged on said second assembly surface of said interior circuit board, and a main body of said quartz crystal is a ceramic package with a heating resistor embedded therein, and a top of said ceramic package is sealed by an upper metal lid cover to form an airtight chamber space in an interior of said quartz crystal, and a quartz chip is mounted on said ceramic package through at least one piece of electricity conduction glue and arranged in said airtight chamber space; and
a temperature-controlled circuit and an oscillation circuit arranged on said first assembly surface of said exterior circuit board or said third assembly surface of said interior circuit board.

2. The oven controlled crystal oscillator using the heating device embedded in the quartz crystal package of claim 1, wherein said exterior housing is made of plastic or metal.

3. The oven controlled crystal oscillator using the heating device embedded in the quartz crystal package of claim 1, further comprising a thermistor arranged on said second assembly surface or said third assembly surface of said interior circuit board.

4. The oven controlled crystal oscillator using the heating device embedded in the quartz crystal package of claim 1, wherein said temperature-controlled circuit comprises a temperature-controlled circuit control element and a temperature-controlled circuit adjustment element.

5. The oven controlled crystal oscillator using the heating device embedded in the quartz crystal package of claim 1, wherein said oscillation circuit is formed by an oscillation circuit chip connected with a ceramic package via at least one conduction wire.

6. The oven controlled crystal oscillator using the heating device embedded in the quartz crystal package of claim 5, wherein said temperature-controlled circuit is a discrete circuit or cooperates with said oscillation circuit to form an integrated circuit.

7. An oven controlled crystal oscillator using a heating device embedded in a quartz crystal package comprising:
an exterior housing;
an exterior circuit board arranged on a bottom of said exterior housing and cooperating with said exterior housing to define a hermetic interior chamber space, and a top of said exterior circuit board has a first assembly surface;
an interior circuit board arranged in said interior chamber space and electrically connected with said first assembly surface of said exterior circuit board through a plurality of metal leads, and a top and a bottom of said interior circuit board respectively have a second assembly surface and a third assembly surface;
a first heating resistor arranged on said third assembly surface of said interior circuit board, and a bottom of said first heating resistor has a fourth assembly surface;
a quartz crystal arranged on said fourth assembly surface of said first heating resistor, and a main body of said quartz crystal is a ceramic package with a second heating resistor embedded therein, and a top of said ceramic package is sealed by an upper metal lid cover to form an airtight chamber space in an interior of said quartz crystal, and a quartz blank is fixed on said ceramic package through at least one piece of electricity conduction glue and arranged in said airtight chamber space;
a temperature-controlled circuit arranged on said third assembly surface or said second assembly surface of said interior circuit board or said first assembly surface of said exterior circuit board; and
an oscillation circuit arranged on said first assembly surface of said exterior circuit board.

8. The oven controlled crystal oscillator using the heating device embedded in the quartz crystal package of claim 7, wherein said exterior housing is made of plastic or metal.

9. The oven controlled crystal oscillator using the heating device embedded in the quartz crystal package of claim 7, wherein said first assembly surface of said exterior circuit board further comprises a heat-cut groove.

10. The oven controlled crystal oscillator using the heating device embedded in the quartz crystal package of claim 7, wherein said temperature-controlled circuit comprises a temperature-controlled circuit control element and a temperature-controlled circuit adjustment element.

11. The oven controlled crystal oscillator using the heating device embedded in the quartz crystal package of claim 7, wherein said oscillation circuit is formed by an oscillation circuit chip connected with a ceramic package via at least one conduction wire.

12. The oven controlled crystal oscillator using the heating device embedded in the quartz crystal package of claim 11, wherein said temperature-controlled circuit is a discrete circuit or cooperates with said oscillation circuit to form an integrated circuit.

13. The oven controlled crystal oscillator using the heating device embedded in the quartz crystal package of claim 7, further comprising a thermistor arranged on said third assembly surface of said interior circuit board.

14. The oven controlled crystal oscillator using the heating device embedded in the quartz crystal package of claim 7, wherein a surface of said upper metal lid cover of said quartz crystal tightly touches said fourth assembly surface of said first heating resistor.

15. The oven controlled crystal oscillator using the heating device embedded in the quartz crystal package of claim 14, wherein a surface of said upper metal lid cover of said quartz crystal is fixed to said fourth assembly surface of said first heating resistor through a piece of thermal conduction glue.
